(19) United States
(12) Patent Application Publication
(10) Pub. No.: US 2016/0366790 A1
(43) Pub. Date: Dec. 15, 2016

(54) HEAT DISSIPATION DEVICE AND HEAT DISSIPATION SYSTEM

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: CHIN-WEN YEH, New Taipei (TW); ZHI-JIAN PENG, Wuhan (CN)

(21) Appl. No.: 14/788,482

(22) Filed: Jun. 30, 2015

(30) Foreign Application Priority Data
Jun. 11, 2015 (CN) 201510318243.4

(51) Int. Cl. H05K 7/20

(52) U.S. Cl. CPC H05K 7/20409

(57) ABSTRACT

A heat dissipation device includes a plate and a plurality of shaped fins. The plurality of fins extends from the plate. The plate includes a fixing portion located on one side of an air inlet and a heat dissipation portion extending from the fixing portion. The heat dissipation portion includes a side portion. The side portion includes at least two side edges connected with each other. The end of each fin is identically slanted, a side end is opposite to the slant end. The side end of each fin is aligned with one of the two side edges. A heat dissipation system is also provided.

### CROSS-REFERENCE TO RELATED APPLICATIONS

This application claims priority to Chinese Patent Application No. 201510318243.4 filed on Jun. 11, 2015, the contents of which are incorporated by reference herein.

### FIELD

The subject matter herein generally relates to cooling of heat-generating devices.

### BACKGROUND

Electronic devices include one or more of a circuit, processor, or resistor. As the electronic device operates the one or more of a circuit, microprocessor, or resistor, heat is generated. The heat generated can cause the electronic device to not operate efficiently or even become damaged.

### BRIEF DESCRIPTION OF THE DRAWINGS

Implementations of the present technology will now be described, by way of example only, with reference to the attached figures.

FIG. 1 is an isometric view of one embodiment of a heat dissipation device.

FIG. 2 is a top view of the heat dissipation device of FIG. 1.

FIG. 3 is an exploded, isometric view of the heat dissipation device of FIG. 1 with a heat conduction plate.

FIG. 4 is an isometric view of the heat dissipation device and the heat conduction plate of FIG. 3 mounted to an electronic device.

FIG. 5 is similar to FIG. 4, but viewed from another angle.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to a heat dissipation device. The heat dissipation device includes a plate and a plurality of fins. The plurality of fins extends from the plate. The plate includes a fixing portion located on one side of an air inlet and a heat dissipation portion extending from the fixing portion. The heat dissipation portion includes a side portion. The side portion includes at least two side edges connected with each other. The plurality of fins includes a slant end and a side end opposite to the slant end. The slant end of the plurality of fins forms one straight line. The side end of the plurality of fins is aligned with one of the two side edges.

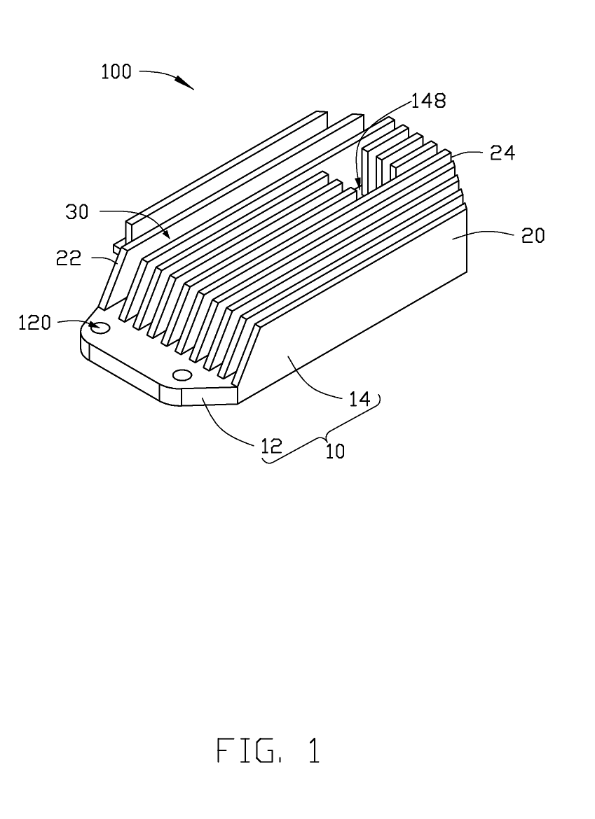

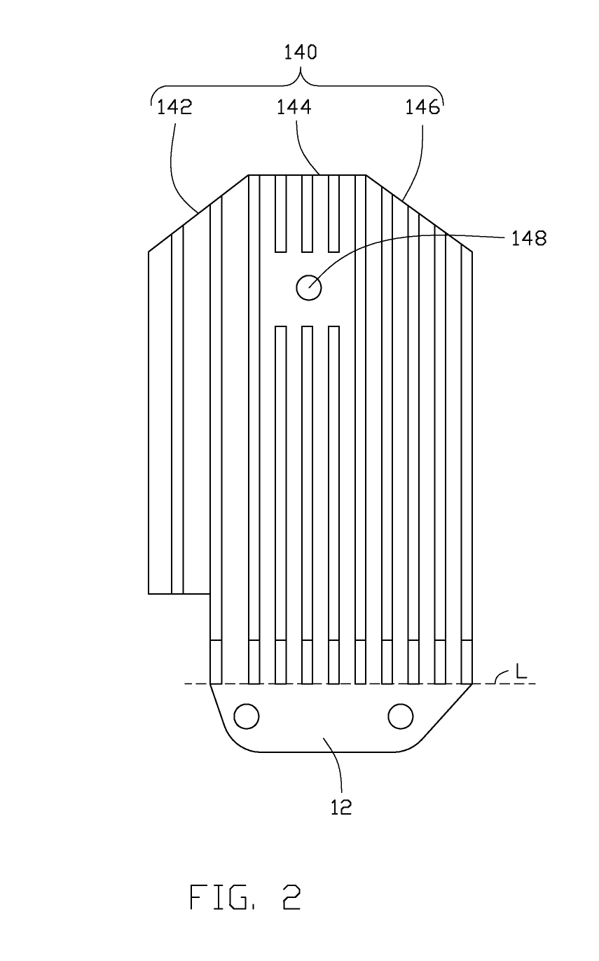

FIGS. 1-2 illustrate one embodiment of a heat dissipation device 100. The heat dissipation device 100 includes a plate 10 and a plurality of fins 20. The plurality of fins 20 extends from the plate 10.

The plate 10 includes a fixing portion 12 and a heat dissipation portion 14 extending from the fixing portion 12. The fixing portion 12 defines two fixing holes 120. The heat dissipation portion 14 includes a side portion 140 and defines a locking hole 148. The side portion 140 is located away from the fixing portion 12 and can include a first side edge 142, a second side edge 144, and a third side edge 146. The first side edge 142 and the third side edge 146 extend from opposite ends of the second side edge 144 and are symmetrical with each other around the lengthways centerline of the plate 10. In one embodiment, the second side edge 144 can be substantially perpendicular to an extending direction of each fin 20. A connecting line of the first side edge 142, the second side edge 144, and the third side edge 146 can form a shape that is substantially an isosceles trapezoid. The fixing portion 12 can be substantially an isosceles trapezoid. The fixing portion 12 and the heat dissipation portion 14 are in a same plane.

Each fin of the plurality of fins 20 is spaced apart and all the fins are substantially parallel. An air flue 30 is formed between two adjacent fins 20. Each fin 20 includes a slant end 22 and a side end 24. The slant end 22 is located on one end of each fin 20 near the fixing portion 12 and the angle of the slant is inclined towards a direction away from the fixing portion 12. The slant ends 22 of the fins 20 together substantially form a flat plane and a line L across all the slant ends 22 (see FIG. 2) is straight. The straight line L is located on a juncture of the fixing portion 12 and the heat dissipation portion 14. A fixed acute angle is defined between any slant end 22 and the plate 10. The side end 24 of each fin 20 is aligned with the side portion 140. In one embodiment, the plate 10 can be a rectangle. The heat dissipation device 100 can be integrally formed.

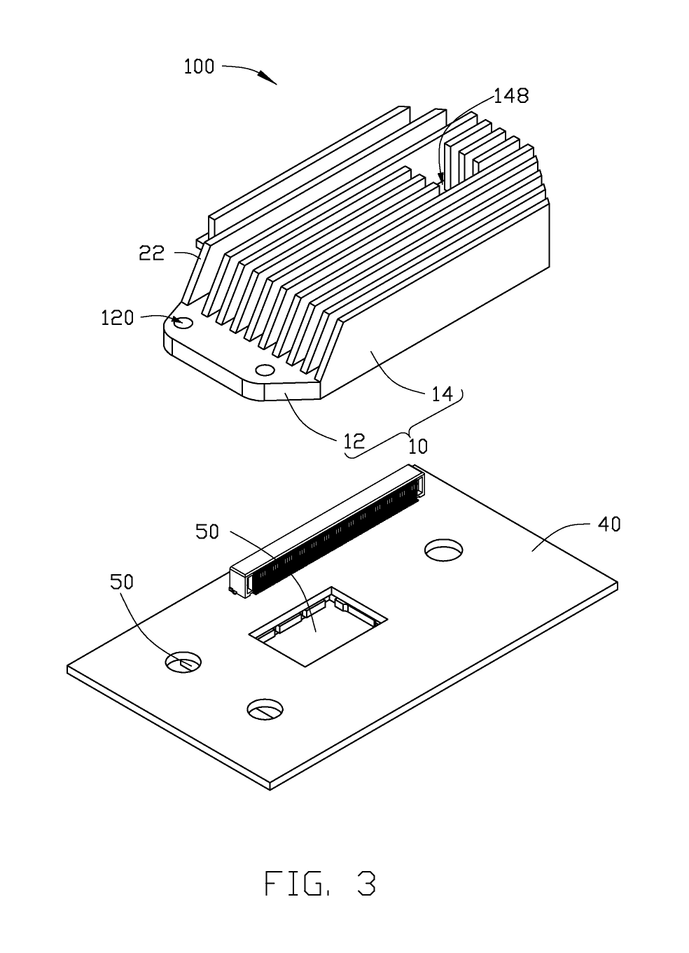

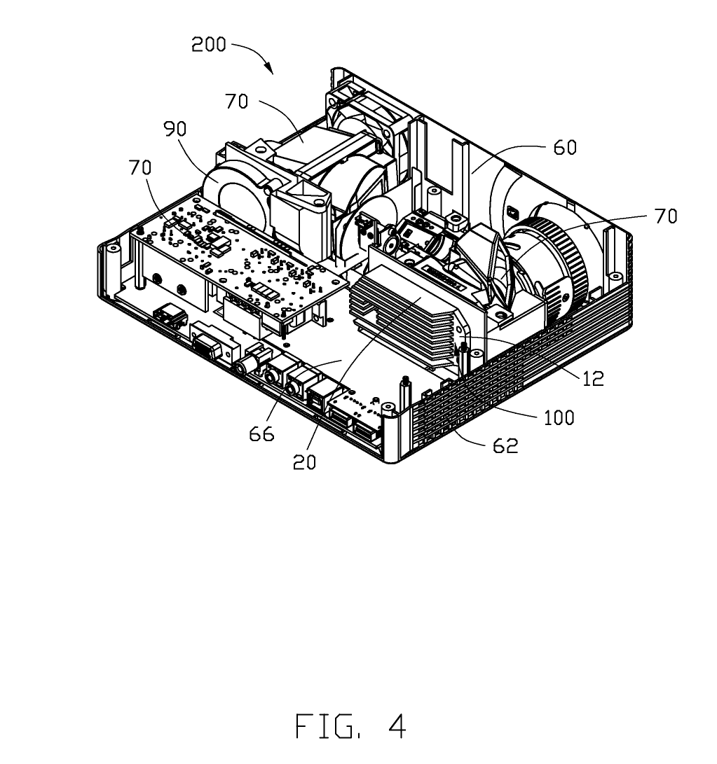

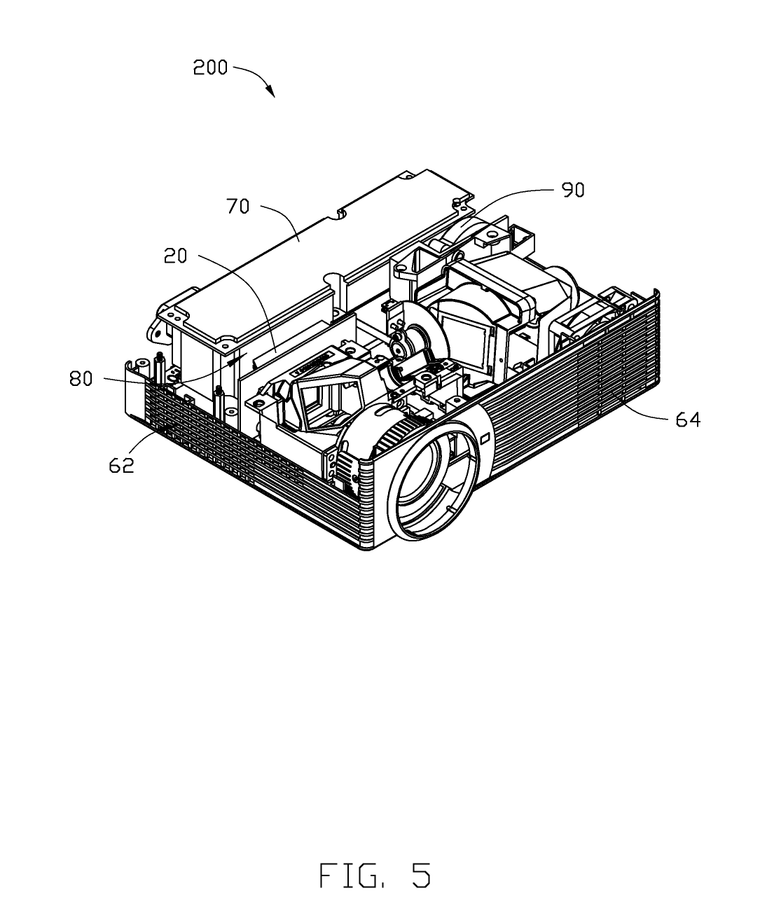

FIGS. 3-5 illustrate the heat dissipation device 100 in a working state. A heat-generating element 50 is fixed to one side of a heat conduction plate 40. The heat dissipation device 100 is fixed to one opposite side of the heat conduction plate 40 via the two fixing holes 120 and the locking hole 148. The plate 10 is located on the heat conduction plate 40. The heat-generating element 50 is located between the two fixing holes 120 and the locking hole 148 and on the center of the plate 10. An electronic device 200 includes a housing 60 and a plurality of electronic elements 70. The housing 60 defines an air inlet 62 and an air outlet 64. The plurality of electronic elements 70 is located on opposite ends of the housing 60 to form a heat dissipation channel 80. The heat dissipation device 100 is located on one side of the air inlet 62 of the housing 60 and is received in the heat dissipation channel 80. The fixing portion 12 is closer to the air inlet 62 than the heat dissipation portion 14. The housing 60 includes a bottom 66. The heat conduction plate 40 can be substantially perpendicular to the bottom 66. Each fin 20 can be substantially parallel to the bottom 66.

When the electronic device 200 is working, the heat from the heat-generating element 50 is conducted to the heat dissipation device 100 via the heat conduction plate 40. The airflow arrives at the fixing portion 12 earlier than the heat dissipation portion 14. The temperature of the side portion 140 is lower than other portion of the heat dissipation portion 14, because the heat-generating element 50 is located between two fixing holes 120 and the locking hole 148, and the side portion 140 is away from the heat heat-generating element 50. Heat from the heat-generating element 50 is absorbed by the plurality of fins 20. Additionally, the heat from the heat-generating element 50 is dissipated by the fins 20 which are adjacent to the first side edge 142, the second side edge 144, and the third side edge 146. The airflow flows through the fixing portion 12, the air flues 30, and the heat dissipation channel 80, and out of the electronic device 200 by two fans 90 via the air outlet, so that all the heat generated can be taken by the heat dissipation device 100.

The embodiments shown and described above are only examples. Many details are often found in the art such as the other features of the heat dissipation device. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dissipation device comprising:
a plate comprising a fixing portion and a heat dissipation portion extending from the fixing portion, the heat dissipation portion comprising a side portion, and the side portion comprising at least two side edges connected with each other;
a plurality of fins extending from the plate, each of the plurality of fins comprising a slant end and a side end opposite to the slant end; and
wherein the slant ends of each of the plurality of fins are aligned in a straight line, and the side ends of each of the plurality of fins are aligned with one of the two side edges.

2. The heat dissipation device of claim 1, wherein the at least two side edges comprises a first side edge, a second side edge, and a third side edge, and the first side edge and the third side edge extend from the opposite ends of the second side edge and are symmetrical with each other.

3. The heat dissipation device of claim 2, wherein the second side edge is substantially perpendicular to an extending direction of each fin.

4. The heat dissipation device of claim 1, wherein an acute angle is defined between the slant end and the plate.

5. The heat dissipation device of claim 1, wherein the straight line is located on a juncture of the fixing portion and the heat dissipation portion.

6. The heat dissipation device of claim 5, wherein the straight line is substantially parallel to the plate.

7. The heat dissipation device of claim 1, wherein the fixing portion defines at least one fixing hole, the heat dissipation portion defines a locking hole, and a heat-generating element is located between the at least one fixing hole and the locking hole.

8. The heat dissipation device of claim 1, wherein the heat dissipation device is integrally formed.

9. A heat dissipation system comprising:
a housing defining an air inlet and an air outlet;
a heat-generating element mounted in the housing;
a heat dissipation device fixed to the heat-generating element, the heat dissipation device comprising a heat dissipation portion and a plurality of fins extending from the heat dissipation portion, the heat dissipation portion comprising a side portion, the side portion comprising at least two side edges connected with each other, and each of the plurality of fins comprising a slant end and a side end opposite to the slant end; and
wherein the slant ends of each of the plurality of fins are aligned in a straight line, the side ends of each fin are aligned with one of the two side edges, and the air inlet, the plurality of fins, and the air outlet cooperatively defines a heat dissipation passage to dissipate heat generated by the heat-generating element.

10. The heat dissipation system of claim 9, wherein the at least two side edges comprises a first side edge, a second side edge, and a third side edge, and the first side edge and the third side edge extend from the opposite ends of the second side edge and are symmetrical with each other.

11. The heat dissipation system of claim 10, wherein the second side edge is substantially perpendicular to an extending direction of each fin.

12. The heat dissipation system of claim 9, wherein the heat dissipation device comprises a plate, the plurality of fins extends from the plate, and an acute angle is defined between the slant end and the plate.

13. The heat dissipation system of claim 12, wherein the plate comprises a fixing portion and the heat dissipation portion, the heat dissipation portion extends from the fixing portion, and the straight line is located on a juncture of the fixing portion and the heat dissipation portion.

14. The heat dissipation system of claim 13, wherein the straight line is substantially parallel to the plate.

15. The heat dissipation system of claim 13, wherein the fixing portion defines at least one fixing hole, the heat dissipation portion defines a locking hole, and the heat-generating element is located between the at least one fixing hole and the locking hole.

16. The heat dissipation system of claim 9, wherein the heat dissipation device is integrally formed.

17. The heat dissipation system of claim 9 further comprising a heat conduction plate mounted on the housing, wherein the housing comprises a bottom, and the heat conduction plate is substantially perpendicular to the bottom.

18. The heat dissipation system of claim 17, wherein the heat dissipation device is fixed to the heat conduction plate, each fin is substantially parallel to the bottom.
